(19) United States
(12) Patent Application Publication
(10) Pub. No.: US 2003/0167379 A1
(43) Pub. Date: Sep. 4, 2003

(54) Apparatus and methods for interfacing with cache memory

(76) Inventor: Donald Charles Soltis JR., Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/086,494

(22) Filed: Mar. 1, 2002

(51) Int. Cl. G11C 5/00

(52) U.S. Cl. 711/119; 710/317; 711/3

(57) ABSTRACT

A processing system includes a processor, a main memory, a cache and a crossbar interface between the processor and the cache. In a multiprocessing system, a plurality of main memory address ranges can be mapped to a plurality of caches, and a plurality of caches can be mapped to a plurality of processors. Thus a significant degree of flexibility is provided in configuring a processing system.

### FIELD OF THE INVENTION

The present invention relates generally to processing systems and, more particularly, to interfacing with cache memory in processing systems.

### BACKGROUND OF THE INVENTION

In multiprocessing systems, a plurality of processors and other system agents such as caches and memories can be fabricated on a single die. Configuring the die in a manner that suits a variety of target applications, however, can be difficult. It might be desirable for a given system, for example, to vary cache sizes and structures according to how frequently data would be requested from main memory addresses during target applications. A given processor might benefit from a large cache, while another processor in general might be slowed down by a large cache. Although increasing a cache size can enhance performance of a processor, diminishing returns can set in as cache latency increases.

It would be desirable to have flexibility in configuring cache memory on a multiprocessor die, so that a single die configuration could accommodate both cache-use-intensive applications and those making relatively little use of cache. Additionally, it would be desirable to be able to increase cache memory available to a processor on such a die without unduly increasing cache latency.

### SUMMARY OF THE INVENTION

The invention, in one embodiment, is directed to a processing system including a processor, a main memory, and a cache configured to receive data from an address of the main memory upon a request for the data by the processor. The processing system includes a crossbar interface between the processor and the cache. When a multiprocessing system is configured in accordance with the above-described embodiment, a plurality of main memory address ranges can be mapped to a plurality of caches, and a plurality of caches can be mapped to a plurality of processors. The processors and the caches are linked via the crossbar interface.

Cache sizes can be changed for a particular system design without changing the crossbar interface. Additional caches can be added to a design to accommodate additional main memory and/or individual processor needs, without significantly increasing latency. The caches can be configured so that some or all of the processors share them. An entire main memory or a portion thereof can be mapped onto a cache, and a processor can associate an entire main memory or a portion thereof with a single cache or with different caches. The above embodiments provide a significant degree of flexibility in configuring a processing system.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a diagram of a processing system of the prior art;

FIG. 2 is a diagram of a processing system according to one embodiment of the present invention;

FIG. 3 is a diagram of a conceptualization of a cache memory mapping scheme according to one embodiment;

FIG. 4 is a diagram of a conceptualization of a request transaction sent by a processor according to one embodiment;

FIG. 5 is a diagram of a conceptualization of a return transaction sent by a cache according to one embodiment;

FIG. 6 is a diagram of a conceptualization of return transactions sent by a memory controller according to one embodiment; and

FIG. 7 is a diagram of an embodiment of a multi-processing system.

### DETAILED DESCRIPTION OF THE PREFERRED EMBODIMENTS

The following description of the preferred embodiments is merely exemplary in nature and is in no way intended to limit the invention, its application, or uses.

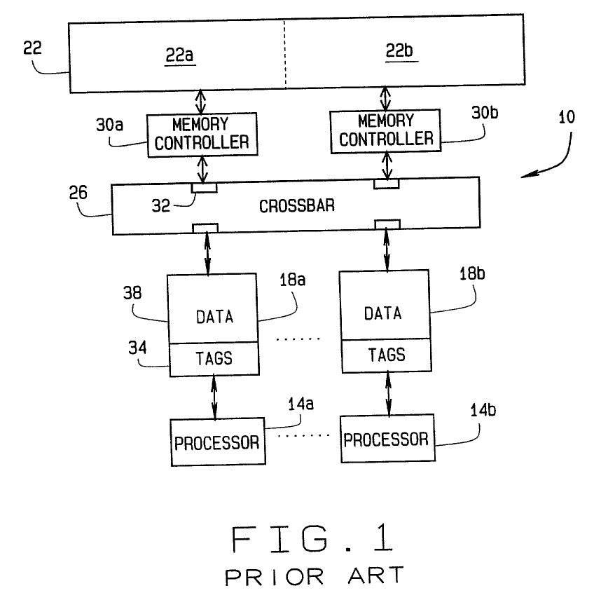

An exemplary multi-processing system of the prior art is indicated generally by reference number 10 in FIG. 1. The system 10 includes a plurality of processors 14, each processor having a cache 18 for holding data utilized by the processor 14. Each cache 18 is configured to receive lines of data requested by the associated processor 14 from a main memory 22. A crossbar 26 links the caches 18 with two memory controllers 30 via ports 32. Each controller 30 controls the reading of data from, and the writing of data to, half of the main memory 22. Specifically, the memory controller 30a controls addresses in one half 22a, and the memory controller 30b controls addresses in the other half 22b, of the main memory 22.

Data storage addresses in both halves of the main memory 22 are mapped onto each of the caches 18. When, for example, the processor 14a requests data from the main memory 22, the request is directed to the associated cache 18a. A tag array 34 of the cache 18a is searched to determine whether the data already is stored in a cache data array 38 of the cache 18a. If a cache hit occurs, i.e. if it is determined that the data is already in the cache 18a data array 38, the data is returned from the cache 18a to the processor 14a.

If a cache miss occurs, i.e. if it is determined that the data is not in the cache 18a data array 38, the data is retrieved from the main memory 22 via the memory controller 30 controlling the address of the requested data. The retrieved data is transmitted via the crossbar 26 to the data array 38 of the cache 18a. The data then is transferred from the cache 18a to the processor 14a.

Data from an address of the main memory 22 may be stored in a cache 18 and subsequently changed by the associated processor 14. A coherency scheme typically is used to maintain data coherency, for example, in the event that the processor updates its associated cache 18 with the changed data. Such schemes are designed to ensure that the most recent data is written to the main memory 22 and/or other caches 18. Information used in maintaining cache coherency typically is stored in the tag array 34 of a cache 18. Such information can be updated, for example, when the cache 18 receives data from the main memory 22 and/or the associated processor 14.

The crossbar 26 makes it possible for a memory controller 30 to update two caches 18 with the same data at the same time, i.e. within the same system 10 clock cycle. Each processor 14, however, obtains the updated data indirectly, that is, from its associated cache 18 after the associated cache 18 has been updated by a memory controller 30.

Increasing the size of a given cache 18 allows the cache 18 to hold, at any one time, a greater number of lines of data from main storage 22 than prior to the increase. Thus, generally, performance of a processor 14 can improve when the associated cache 18 is enlarged. As a size of a cache 18 is increased, however, the latency, i.e. time needed to return data to the associated processor 14 from the cache 18, also increases. Latency increases at least in part because a processor 14 typically is configured to wait for a fixed time period for an outstanding data request. As the size of the cache 18 is increased, this fixed processor wait time also typically is increased to allow for data searches over the enlarged cache memory area. Specifically, the processor 14 typically is hardware-reconfigured to increase the wait time. Thus processor 14 performance and flexibility can be limited by cache 18 performance, which also can affect the overall performance of the system 10. Such can be the case particularly where the system 10 resides on a single die.

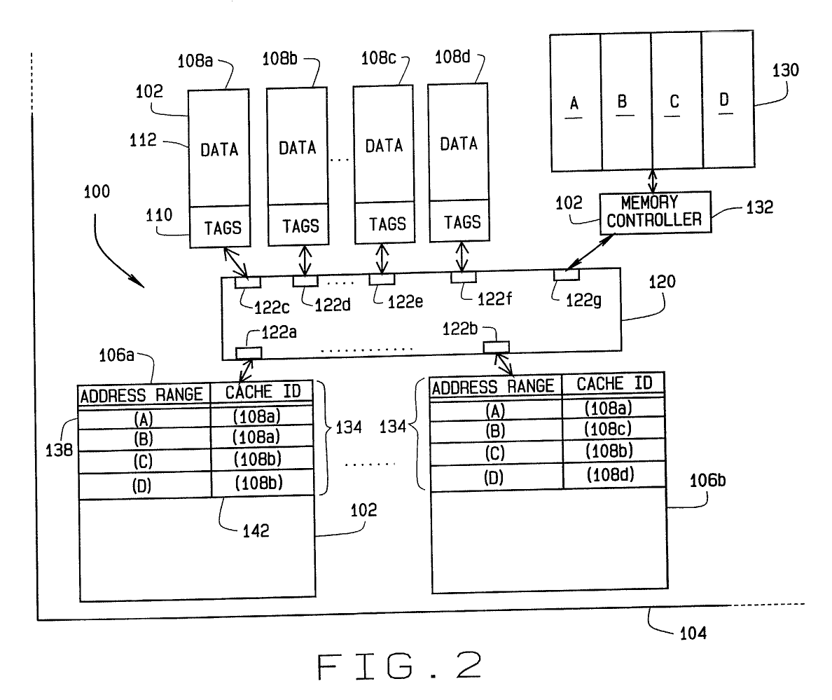

A processing system according to one embodiment of the present invention is indicated generally by reference number 100 in FIG. 2. The system 100 includes a plurality of system agents or modules 102 interconnected to perform system functions. Generally, the modules 102 communicate with one another by (a) issuing requests for data and/or (b) transmitting data in response to such requests. As shall be further described below, each module 102 is identified within the system 100 by a unique module identifier (module ID) used for routing communications, or transactions, between sender and recipient.

The system 100 is configured on a single die 104. Modules 102 of the system 100 include a plurality of processors 106 and a plurality of cache memories or caches 108. It is contemplated, however, that other embodiments can include as few as a single processor 106 and/or a single cache 108, and that other embodiments can be configured on more than one die. Each cache 108 includes a tag array 110 and a data array 112.

A crossbar interface 120 links system agents 102 such as the processors 106 and caches 108 via a plurality of ports 122. Specifically, the caches 108a, 108b, 108c and 108d access the crossbar 120 via ports 122c, 122d, 122e and 122f respectively, and the processors 106a and 106b access the crossbar 120 via ports 122a and 122b respectively. When a plurality of modules 102 communicate with one another via transactions across the crossbar 120, sender and recipient module IDs are included in each transaction. The module IDs are checked against a route table (not shown) to identify a crossbar port 122 for each of the communicating modules 102. The transaction then is routed across the crossbar 120 between the appropriate ports 122. More than one transaction at a time can be transmitted through the crossbar 120, and a module 102 can send transactions to more than one receiving module 102 within the same system 100 clock cycle. In the event that a module 102 sends a transaction asynchronously to the crossbar 120, the crossbar 120 provides synchronization for such transaction.

A main memory 130 is linked to the crossbar 120 via a memory controller 132 at port 122g. As shall be further described below, address ranges A, B, C and D of the main memory 130 are mapped onto the caches 108. In the present exemplary embodiment, all of the address ranges A, B, C and D are mapped onto each of the caches 108. Various other mappings, however, are possible. All, or alternatively, fewer than all, ranges of the memory 130 may be mapped, for example, onto fewer than all of the caches 108. A given cache 108 is configured to receive data from addresses of the main memory 130 mapped to that cache, upon a processor 106 request for the data.

Generally, a given processor 106 can be associated with one or a plurality of the caches 108, and a given cache 108 can be associated with one or a plurality of the processors 106, as shall now be described. Each of the processors 106 includes a programmable table 134 of address ranges 138 addressable by the given processor 106. For each address range 138, the table 134 includes a module ID 142 identifying a cache 108 to which the address range 138 is mapped.

For example, and as shall be further described below, the processor 106a obtains cache data corresponding to main memory address ranges A and B via the port 122c, which links to the cache 108a. The processor 106a obtains cache data corresponding to address ranges C and D via the port 122d, which links to the cache 108b. The processor 106b obtains cache data for ranges A through D from caches 108a through 108d respectively, via crossbar ports 122c through 122f respectively.

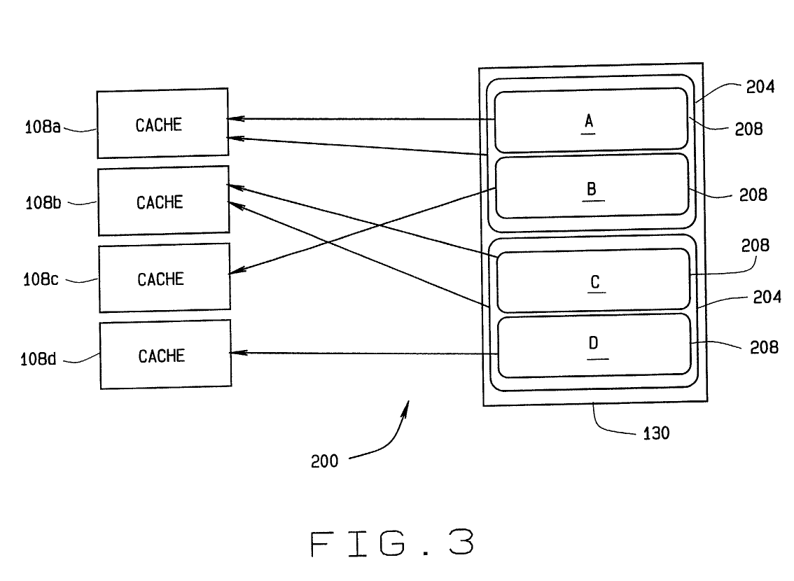

Association of caches 108 with processors 106 as described with reference to FIG. 2 is further illustrated in FIG. 3, wherein the mapping of the main memory 130 onto caches 108 by processors 106 is generally indicated by reference number 200. As previously described, the table 138 of the processor 106a makes an association 204 of the memory ranges A and B with cache 108a, and of the ranges C and D with cache 108b. The table 138 of the processor 106b makes an association 208 of memory range A with cache 108a, memory range B with cache 108c, memory range C with cache 108b, and memory range D with cache 108d. (It should be obvious that the associations 204 and 208 and the memory ranges A-D are drawn in FIG. 3 so as to conceptualize their interrelationships in connection with the mapping 200. Thus their extents relative to the main memory 130 and relative to one other are only approximated in FIG. 3.)

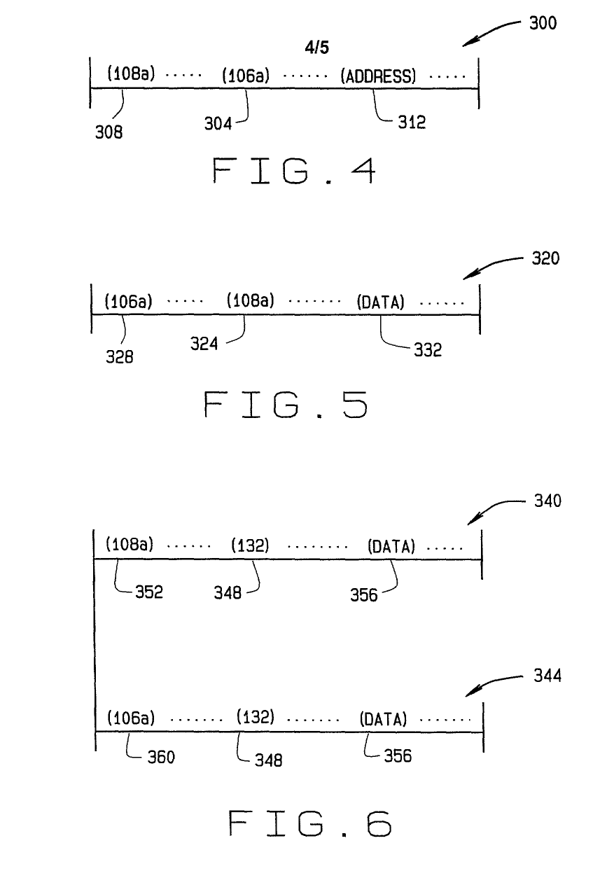

When the processor 106a requests data stored at an address within the main memory address range A, a request transaction, for example, a request indicated generally by reference number 300 in FIG. 4, is sent to the cache 108a. The request 300 includes a module ID 304 identifying the sending processor 106a. A module ID 308 identifying the recipient cache 108a is obtained from the address range table 134 (shown in FIG. 2) and included in the request 300. The request 300 also includes the main memory address 312 from which data is being requested. Other data of course may be included in the request 300, for example, to distinguish the request 300 from any other request(s) that may be pending between the two modules 106a and 108a. It should be understood that FIGS. 4 through 6 represent conceptualizations, and that many transaction elements, data and control formats, and transaction protocols are possible. The route table (not shown) is used to match the module IDs 304 and 308 with ports 122a and 122c respectively, and the crossbar 120 links the processor 106a with the cache 108a via the ports 122a and 122c.

A tag lookup is performed in the tag array 110 of the cache 108a, as known in the art, to determine whether the requested data is in the cache 108a. If a cache hit occurs, the requested data is returned via the crossbar 120 to the processor 106a in a data return transaction, for example, a return transaction indicated generally by reference number 320 in FIG. 5. The return transaction 320 includes module IDs 324 and 328 identifying the sending and receiving modules 108a and 106a respectively, as well as data 332 requested by the processor 106a. The module IDs are checked against the route table, as previously described, and the return transaction 320 is routed through ports 122c and 122a of the crossbar 120 to the processor 106a.

If a cache miss occurs, the request 300 is forwarded to the memory controller 132, which obtains the requested data from the range A of the main memory 130 (shown in FIG. 2). The memory controller 132 returns the requested data through the crossbar 120 in two parallel transactions, for example, transactions indicated by reference numbers 340 and 344 in FIG. 6. The transaction 340 is sent to the cache 108a and includes a module ID 348 identifying the sending memory controller 132, a module ID 352 identifying the receiving cache 108a, and requested data 356. The transaction 344 is sent to the processor 106a and includes the memory controller module ID 348, the requested data 356, and a module ID 360 identifying the receiving processor 106a. The cache 108a updates its data array 112 with the new data and updates its tag array 110 with new tag information. Cache coherency can be maintained using coherency schemes as previously described in connection with the prior art system 10. For example, the memory controller 132 can update the data array 112, and tag array 110, of any other cache 108 that had previously requested data from the same memory range A address.

Where it is desired to increase the main memory 130 for a particular processing system configuration, size(s) of one or a plurality of caches 108 can be changed so that additional memory can be mapped onto the cache(s) 108 without changing the crossbar 120 interface. Caches 108 also can be added to or removed from the processing system 100, for example, to accommodate changes in the memory ranges being mapped to the caches 108. The table 134 of a given processor 106 is programmable to increase or reduce a number of caches 108 associated with the processor 106 and/or to change the main memory ranges 138 mapped onto caches 108.

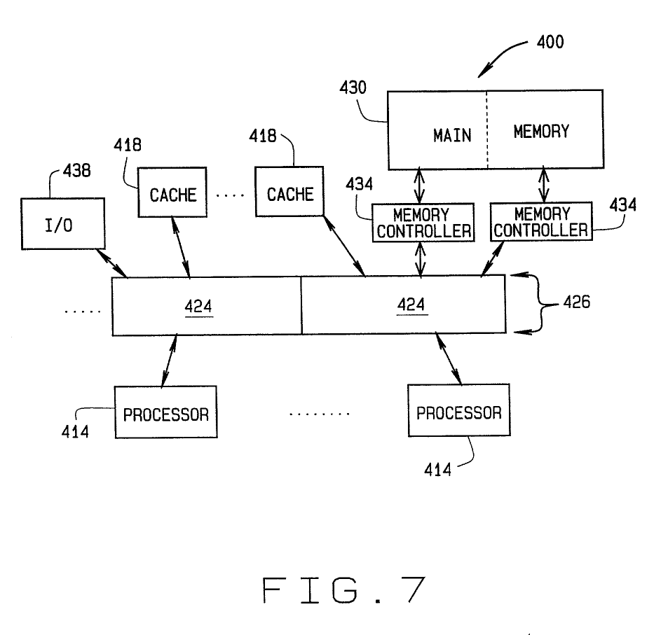

A multi-processing system according to another embodiment of the present invention is indicated generally by reference number 400 in FIG. 7. The system 400 includes a plurality of processors 414 linked to a plurality of caches 418 via a plurality of crossbars 424 joined to form an interface 426. A main memory 430 is mapped onto the caches 418 and also is linked to the crossbar interface 424 via two memory controllers 434. Additional agents of the system 400 are linked to the interface 424, including, for example, an input/output system 438.

The above described embodiments make it possible to modify a particular die design easily, to suit the cache needs of particular processors and target applications. Within a given multiprocessing system, each processor can be mapped with only as much cache as may be beneficial (which can differ between processors within the system). Additionally, a processor can be mapped to utilize different caches for different main memory ranges. Thus latency can be minimized.

The above-described crossbar interface provides high-speed linkage among processors and caches. The crossbar interface also makes it possible to provide for asynchronous communication between a processor and a cache. Cache lookup, and cache data retrieval, can be performed more rapidly than with conventional cache structures. The above embodiments make it possible to update a cache memory and associated processor in parallel, instead of having to move the data to the cache and then move the data from the cache to the processor. Because the above cache memories can be easily changed in size for a particular multiprocessor configuration, a processor can be easily configured with a cache size appropriate for a particular use. Additionally, the caches can be changed in number, e.g. increased in number for a given configuration without increasing latency.

The above-described ability of processors to share caches (and/or portions thereof) makes possible a wide variety of mappings, of caches onto processors and of main memory onto caches. Hence it is possible to configure a wide variety of processing system characteristics without having to change the crossbar interface. A particular die configuration thus can be utilized for a wider variety of applications than would be possible with die configurations having conventionally integrated processors and caches.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A processing system including a processor, a main memory, and a cache configured to receive data from an address of the main memory upon a request for the data by the processor, the processing system comprising a crossbar interface between the processor and the cache.

2. The processing system of claim 1 wherein the main memory is controlled by a memory controller, the crossbar interface configured to link the memory controller, the processor and the cache.

3. The processing system of claim 1 wherein the crossbar interface comprises a plurality of ports via which the cache and the processor are linked based on the main memory address.

4. The processing system of claim 1 wherein the processor is configured to associate at least one main memory address range with the cache.

5. The processing system of claim 4 wherein the processor is linked with the cache based on an address range stored in the processor and corresponding to a range of addresses of the main memory mapped to the cache.

6. The processing system of claim 1 wherein at least one range of addresses of the main memory is mapped to the cache.

7. The processing system of claim 1 further comprising a plurality of caches, the processor comprising an address range table wherein each address range is associated with a cache.

8. The processing system of claim 7 wherein the address range table is programmable to change at least one of an address range and a cache associated with the processor.

9. The processing system of claim 1 further comprising a plurality of caches, the processor comprising a plurality of address ranges and module identifiers corresponding to the caches.

10. The processing system of claim 9 wherein the crossbar interface comprises a plurality of ports, the crossbar interface configured to link a cache with the processor via a port associated with an address range in the main memory.

11. The processing system of claim 1 wherein the crossbar interface is configured to return the data requested by the processor to the cache and the processor in parallel.

12. The processing system of claim 1 wherein the crossbar interface comprises at least one crossbar.

13. The processing system of claim 1 further comprising a plurality of processors linked with the cache via the crossbar interface.

14. A processing system comprising a plurality of processors, a main memory, a plurality of caches, and a crossbar interface linking the caches and the processors, each cache configured to receive data from a range of the main memory upon a request for the data by one of the processors.

15. The processing system of claim 14 wherein the processors are configured to share at least one of the caches via the crossbar interface.

16. The processing system of claim 14 wherein the crossbar interface links one of the caches and one of the processors based on a module identifier supplied by the processor.

17. The processing system of claim 16 wherein the module identifier is associated by the supplying processor with a main memory address range.

18. The processing system of claim 14 wherein the crossbar interface is configured to provide signal synchronization for an asynchronous transaction between one of the caches and one of the processors.

19. The processing system of claim 14 further comprising at least one memory controller configured to send data from the main memory to a receiving cache and a requesting processor at the same time.

20. A method for configuring a multi-processor processing system comprising the steps of:
mapping a plurality of main memory address ranges to a plurality of caches;
mapping the caches to a plurality of processors; and
linking the processors and the caches using a crossbar interface.

21. The method of claim 20 further comprising the step of configuring a processor to interface with a cache to which is mapped a main memory address range addressable by the processor.

22. The method of claim 20 wherein the step of mapping the caches to a plurality of processors comprises associating, in a processor, a main memory address range with a module identifier for a cache.

23. The method of claim 20 wherein the step of mapping the caches to a plurality of processors comprises mapping a cache to more than one processor.

24. The method of claim 20 further comprising the step of changing a size of a cache, said step performed without changing the crossbar interface.

25. The method of claim 20 further comprising the step of configuring the processing system on a single die.

26. The method of claim 20 wherein the step of mapping the caches to a plurality of processors comprises mapping more than one cache to one processor.
